(19) United States
(12) Patent Application Publication
(10) Pub. No.: US 2025/0329373 A1
(43) Pub. Date: Oct. 23, 2025

(54) MEMORY, OPERATION METHODS, MEMORY SYSTEMS, AND ELECTRONIC DEVICES

(71) Applicant: Yangtze Memory Technologies Co., Ltd., Wuhan (CN)

(72) Inventors: ZhiChao Du, Wuhan (CN); Xiang Fu, Wuhan (CN); Yu Wang, Wuhan (CN); Yang Xiang, Wuhan (CN)

(21) Appl. No.: 18/800,938

(22) Filed: Aug. 12, 2024

(30) Foreign Application Priority Data
Apr. 19, 2024 (CN) 202410480343.6

(51) Int. Cl. G11C 11/4091; H01L 23/00; H01L 25/065; H01L 25/18; H10B 80/00

(52) U.S. Cl. CPC G11C 11/4091; H01L 24/08; H01L 25/0657; H01L 25/18; H10B 80/00; H01L 2224/08145; H01L 2924/1431; H01L 2924/1436

(57) ABSTRACT

Implementations of the present disclosure include a memory, an operation method, and a memory system, and relate to the field of storage technology. The memory includes a sensing amplifier SA and a plurality of memory cells, the plurality of memory cells are coupled to a bit line, the bit line is connected to the SA, and the SA includes a first transistor and a second transistor; wherein the first transistor is coupled with a first voltage source of the SA or a second voltage source of the SA; and wherein the second transistor is coupled with the bit line and capable of being controlled with a gate voltage of not less than 1.5V.

### CROSS-REFERENCE TO RELATED APPLICATION

This application claims priority to and the benefit of Chinese Patent Application 202410480343.6, filed on Apr. 19, 2024, which is hereby incorporated by reference in its entirety.

### TECHNICAL FIELD

Implementations of the present application relate to the field of storage technology, particularly to memory, operation methods, memory systems and electronic devices.

### BACKGROUND

A sensing amplifier (SA) is an important device in a memory, which can amplify a weak signal generated by a memory cell during a charging and discharging process, thereby reading and writing the memory cell.

### BRIEF DESCRIPTION OF DRAWINGS

FIG. 1 is a schematic diagram of a sensing amplifier provided in one implementation of the present application;

FIG. 2 is a schematic diagram of a memory provided in one implementation of the present application;

FIG. 3 is a schematic diagram of a memory cell provided in one implementation of the present application;

FIG. 4 is a structure schematic diagram of a memory provided in one implementation of the present application;

FIG. 5 is a structure schematic diagram of a memory provided in another implementation of the present application;

FIG. 6 is a schematic diagram of a multi-level architecture of a memory provided in one implementation of the present application;

FIG. 7 is a schematic diagram of the connection relationship of a sensing amplifier group, a word line driver group, and a memory cell array provided in one implementation of the present application;

FIG. 8 is a schematic diagram of an overlap case of the projections of a sensing amplifier group, a word line driver group, and a memory cell array provided in one implementation of the present application;

FIG. 9 is a schematic diagram of an operation method of a memory provided in one implementation of the present application;

FIG. 10 is a schematic diagram of an operation timing of a sensing amplifier provided in one implementation of the present application;

FIG. 11 is a structure block diagram of an electronic device provided in one implementation of the present application; and

FIG. 12 is a structure block diagram of an electronic device provided in another implementation of the present application.

Legend explanation:

| | |
|---|---|
| 100: memory | 10: SA |
| 20: memory cell | 30: bit line |
| 11: first transistor | 12: second transistor |
| 13: first voltage source | 14: second voltage source |
| 12-1: first N-MOS transistor | 12-2: second N-MOS transistor |
| 12-3: third N-MOS transistor | 12-4: fourth N-MOS transistor |
| 30-1: first bit line | 30-2: second bit line |
| 15: fifth N-MOS transistor | 1: first semiconductor structure |
| 2: second semiconductor structure | 40: first bonding structure |
| 50: second bonding structure | 61: first memory cell array |
| 21: first memory cell | 70: first SA group |
| 3: bonding interface | 62: second memory cell array |
| 22: second memory cell | 80: first WLD group |
| 63: third memory cell array | 211: transistor structure |
| 212: capacitor structure | |

### DETAILED DESCRIPTION

In order to make the aim, technical solution, and advantages of the present application clearer, a further detailed description of the implementations of the present application will be provided below in conjunction with the accompanying drawings.

In some implementations, the memory comprises a plurality of memory banks and a peripheral circuit, each bank comprises a plurality of memory cells arranged in an array form in the memory bank, that is, each memory bank comprises at least one memory cell array. The peripheral circuit comprises a decoders (a row decoder, a column decoder), an input/output controller, a multiplexer, a sensing amplifier, a word line driver, and any other circuits configured to operate the memory cells. In a memory, a memory cell is coupled to a word line (WL) and a bit line (BL) respectively, wherein the bit line is configured to read and write the memory cell, and the word line is configured to control a connection between the memory cell and the bit line. However, due to a large parasitic capacitance of the bit line, a signal perceived from the bit line during charging and discharging of the memory cell is relatively weak and difficult to be read directly. Therefore, a SA coupled to the bit line is designed in the memory to amplify a weak voltage fluctuation on the bit line, thereby reading and writing the memory cell.

The memory provided in an implementation of the present application comprises the SA. In an example, an implementation of the present application illustrates the memory with a DRAM (Dynamic Random Access Memory) as an example. But it should be understood that the memory is not limited to a DRAM. For example, the memory can also be a SRAM (Static Random Access Memory), a NAND Flash (Not AND Flash), a NOR Flash (Not OR Flash), or any other memories that comprise a sensing amplifier, and the present application is not limited thereto.

The SA comprises a plurality of Metal Oxide Semiconductor Field Effect Transistors (MOSFETs), and the MOSFET comprises an N type MOSFET (also known as an N-channel MOSFET) and a P type MOSFET (also known as a P-channel MOSFET). In the following implementations, for ease of explanation, the MOSFET is briefly referred to as a MOS transistor, the N type MOSFET is briefly referred to as an N-MOS transistor, and the P type MOSFET is briefly referred to as a P-MOS transistor.

In semiconductor technology, due to changes in process and temperature, two theoretically identical MOS transistors in the SA may be mismatched, that is, having different characteristics. For example, two MOS transistors have different threshold voltages, parasitic capacitance, transconductance, etc., which can cause the SA to produce offset noise. For example, it can cause an additional voltage difference between two nodes in the SA (i.e. an offset voltage not caused by a voltage difference between bit lines), leading to the SA incorrectly amplifying information in the memory cell, which can seriously affect memory performance.

In a sensing amplifier, a higher gate voltage is required to control some transistors, which can cause time dependent dielectric breakdown (TDDB) and thus affect the performance of the sensing amplifier.

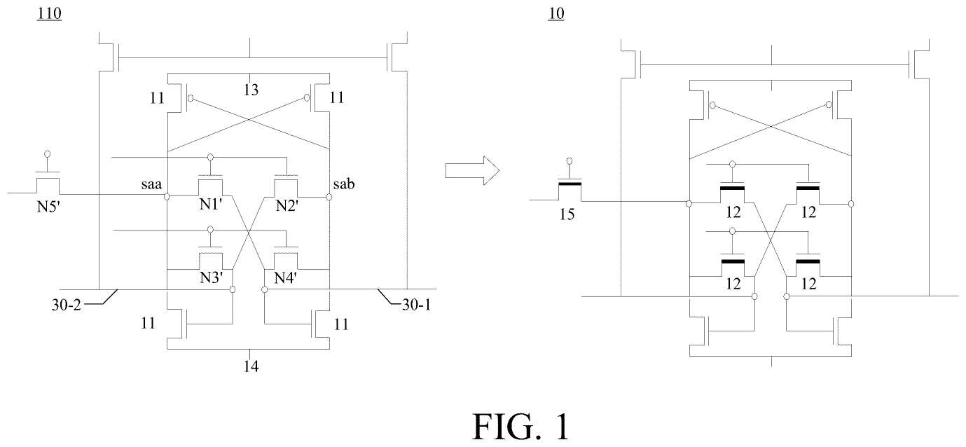

In some implementations, a MOS transistor capable of eliminating offset noise is designed in the SA. Refer to FIG. 1, it illustrates a schematic diagram of a sensing amplifier provided in one implementation of the present application.

A first SA 110 comprises a first transistor 11, a transistor N1′, a transistor N2′, a transistor N3′, a transistor N4′, and a transistor N5′, wherein the first transistor 11 is coupled with a first voltage source 13 or a second voltage source 14 of the first SA 110, and regarding example explanations of the first voltage source 13 and the second voltage source 14, please refer to the following implementations, which will not be elaborated here. The operation voltage ranges of the first transistor 11, the transistor N1′, the transistor N2′, the transistor N3′, the transistor N4′, and the transistor N5′ aforementioned are all 1.1V, that is to say, they are capable of being controlled with gate voltages of around 1.1V. When pre-charging a first bit line 30-1 and a second bit line 30-2, the transistor N1′, the transistor N2′, the transistor N3′, the transistor N4′, and the transistor N5′ will all be turned on, allowing the voltage provided by a pre-charging voltage source (reference voltage Vref) to be applied to the first bit line 30-1 and the second bit line 30-2, thereby flattening the voltages of the first bit line 30-1 and the second bit line 30-2. After the voltages of the first bit line 30-1 and the second bit line 30-2 are flattened, the memory cell that needs to be read and written and the corresponding bit line can be connected by pulling up the voltage of the word line. After the memory cell that needs to be read and written is connected to the corresponding bit line, taking the memory cell that needs to be read and written being coupled to the first bit line 30-1 as an example, when the memory cell stores data 1, the memory cell will discharge to the first bit line 30-1, slightly pulling up the voltage of the first bit line 30-1; when the memory cell stores data 0, the first bit line 30-1 will charge the memory cell, slightly pulling down the voltage of the first bit line 30-1. After the above process, a voltage difference is formed between the first bit line 30-1 and the second bit line 30-2, and the above process can be referred to as an induction stage of the first SA 110. An amplification stage of the first SA 110 is to amplify the voltage difference formed between the first bit line 30-1 and the second bit line 30-2 aforementioned. However, during the amplification stage, due to the first voltage source 13 providing a positive voltage relative to the reference voltage Vref aforementioned, and the second voltage source 14 providing a negative voltage relative to the reference voltage Vref aforementioned, in the event of a mismatch in the first transistor 11, it may cause the first node saa and the second node sab to generate the aforementioned offset voltage. Therefore, in some implementations, an additional offset elimination stage is introduced before the induction stage to eliminate the aforementioned offset voltage. In an example, in the offset elimination stage, the transistor N1′ and the transistor N2′ are turned off, the transistor N3′ and the transistor N4′ are kept on, and the first voltage source 13 is made to provide a positive voltage, while the second voltage source 14 is made to provide a negative voltage. Therefore, before the amplification stage, with both the first and second voltage sources providing corresponding positive and negative voltages, the voltages on the second node sab and the first bit line 30-1 are flattened, and the voltages on the first node saa and the second bit line 30-2 are flattened. The voltage of the bit line after pre-charging is configured to compensate for the aforementioned offset voltage, ultimately achieving the aim of eliminating offset noise. After the offset elimination stage, the first SA 110 can accurately amplify the voltage difference between the first bit line 30-1 and the second bit line 30-2 during the amplification stage.

During the operation of the first SA 110 aforementioned, the gate voltages employed by the aforementioned transistors N1′, N2′, N3′, and N4′ need to be greater than the voltage VDDTH applied for the memory cell to store data 1 (such as 1.015V, which can also be referred to as the array power supply voltage) plus their own threshold voltages. However, as can be seen from the previous implementations, the operation voltage range of each transistor in the first SA 110 is 1.1V. Therefore, a time dependent dielectric breakdown problem is prone to occur to the aforementioned transistors N1′, N2′, N3′, and N4′. In addition, since the transistor N5′ controls the pre-charging of the first bit line 30-1 and the second bit line 30-2 by the pre-charging voltage source, employing a higher gate voltage to turn on the transistor N5′ can improve the pre-charging efficiency and optimize the overall timing, but this also leads to the problem of time dependent dielectric breakdown of the transistor N5′.

In summary, refer to FIG. 1, in some implementations, a second transistor 12 and a fifth N-MOS transistor 15 capable of being controlled with a higher gate voltage are configured to replace the aforementioned transistors N1′, N2′, N3′, N4′ and N5′, resulting in a SA 10 with higher reliability compared to the first SA 110.

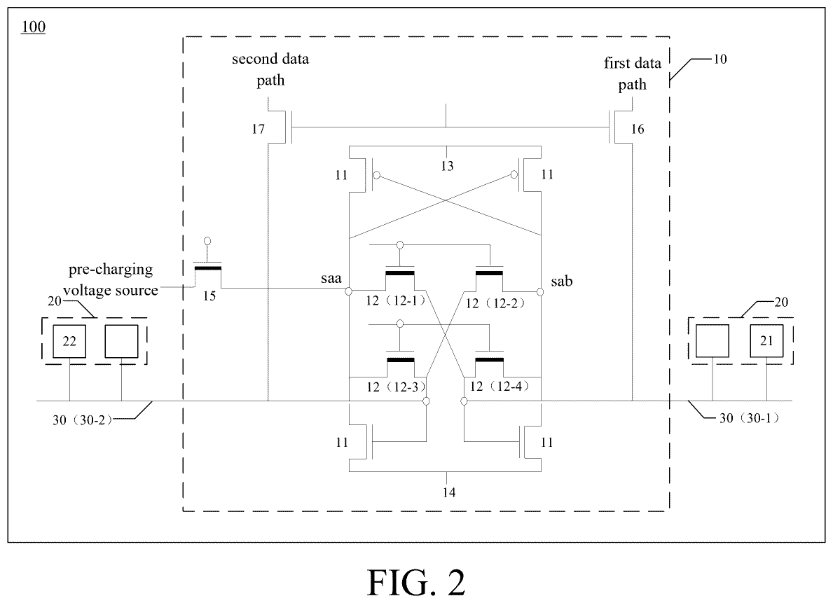

Refer to FIG. 2, it illustrates a schematic diagram of a memory provided in one implementation of the present application. The memory 100 comprises the SA 10 and a plurality of memory cells 20 which are coupled to a bit line 30 connected to the SA 10. The SA 10 comprises a first transistor 11 and a second transistor 12.

In some implementations, the first transistor 11 is coupled with the first voltage source 13 or the second voltage source 14 of the SA 10.

In some implementations, the first voltage source 13 is a positive voltage source of the SA 10 and configured to provide a positive voltage relative to the reference voltage Vref to the SA 10, and the second voltage source 14 is a negative voltage source of the SA 10 and configured to provide a negative voltage relative to the reference voltage Vref to the SA 10. In some implementations, the reference voltage Vref=VDDTH/2.

In some implementations, the P-MOS transistor in the first transistor 11 is coupled with the first voltage source 13, and the N-MOS transistor in the first transistor 11 is coupled with the second voltage source 14.

In some implementations, the second transistor 12 is coupled with the bit line 30, and capable of being controlled with a gate voltage of not less than 1.5V.

The second transistor 12 being capable of being controlled with a gate voltage not less than 1.5V means that the second transistor 12 can maintain normal operation without breakdown when being controlled with a gate voltage not less than 1.5V. For example, the second transistor 12 can maintain normal operation without breakdown within the lifespan of the memory 100 promised to a user, when being controlled with a gate voltage of not less than 1.5V.

In some implementations, the second transistor 12 is capable of being controlled with a voltage greater than or equal to 1.5V and less than or equal to 2.2V.

In some implementations, the first transistor 11 is capable of being controlled with a gate voltage less than 1.5V, for example, the first transistor 11 is capable of being controlled with a gate voltage greater than or equal to 0.8V and less than or equal to 1.3V.

It needs to consider the phenomenon of time dependent dielectric breakdown when selecting the gate voltage supported by transistors. Time dependent dielectric breakdown is a time-dependent dielectric breakdown, i.e. a phenomenon that when a voltage is applied to the gate of a transistor for a certain period of time, the gate oxide layer of the transistor will be broken down. The higher the gate voltage, the shorter the breakdown time, and the higher the probability of occurrence. To improve the phenomenon of time dependent dielectric breakdown while increasing the gate voltage, it is desired to increase the thickness of the gate oxide layer of the transistor.

The gate oxide layer is an oxide dielectric layer configured to isolate the gate of a transistor from the doped regions (drain and source) of the transistor and a conductive channel between the doped regions. The gate oxide layer can comprise SiO2 (silicon dioxide), SiON (silicon oxynitride), and any other suitable dielectric materials, and the present application is not limited thereto.

Transistors with different gate oxide layer thicknesses support different gate voltages. In some implementations, the gate voltage supported by the transistor is increased by increasing the thickness of the gate oxide layer of the transistor.

In some implementations, the thickness the gate oxide layer of the second transistor 12 is at least twice that of the gate oxide layer of the first transistor 11. Therefore, the second transistor 12 is capable of being controlled with a higher gate voltage compared to the first transistor 11.

In some implementations, the second transistor 12 comprises a first N-MOS transistor 12-1, a second N-MOS transistor 12-2, a third N-MOS transistor 12-3, and a fourth N-MOS transistor 12-4.

In some implementations, the bit line 30 comprises a first bit line 30-1 and a second bit line 30-2. The first N-MOS transistor 12-1 and the fourth N-MOS transistor 12-4 are respectively coupled to the first bit line 30-1. The second N-MOS transistor 12-2 and the third N-MOS transistor 12-3 are respectively coupled to the second bit line 30-2.

The first line 30-1 and the second line 30-2 aforementioned are configured to read and write different memory cells.

For example, if in a data reading task, the memory cell to be read is coupled to the first bit line, the data stored in the memory cell can be read by reading the voltage of the first bit line. For example, if the memory cell stores data 1, then after amplifying the voltage difference through the SA 10, the voltage on the first bit line is about 1V, and the voltage on the second bit line is 0V. At this time, the data read from the first bit line is 1. If the memory cell stores data 0, then after amplifying the voltage difference through the SA 10, the voltage on the first bit line is 0V, and the voltage on the second bit line is about 1V. At this time, the data read from the first bit line is 0.

For example, if in a data writing task, the memory cell to be written is coupled to the first bit line, the memory cell can be charged and discharged through the first bit line to write data. For example, if the memory cell stores data 1, then after amplifying the voltage difference through the SA 10, the voltage on the first bit line is about 1V, and the voltage on the second bit line is 0V. At this time, the voltage on the first bit line can be pulled down to 0V to discharge the memory cell and write data 0 to the memory cell. If the memory cell stores data 0, then after amplifying the voltage difference through the SA 10, the voltage on the first bit line is 0V, and the voltage on the second bit line is about 1V. At this time, the voltage on the first bit line can be pulled up to 1V to charge the memory cell and write data 1 to the memory cell.

In some implementations, the first N-MOS transistor 12-1 and the second N-MOS transistor 12-2 are controlled with a same gate voltage, and the third N-MOS transistor 12-3 and the fourth N-MOS transistor 12-4 are controlled with a same gate voltage.

In some implementations, the first N-MOS transistor 12-1 and the second N-MOS transistor 12-2 being controlled with a same gate voltage means that the gates of the first N-MOS transistor 12-1 and the second N-MOS transistor 12-2 are coupled to a same voltage source, and the third N-MOS transistor 12-3 and the fourth N-MOS transistor 12-4 being controlled with a same gate voltage means that the gates of the third N-MOS transistor 12-3 and the fourth N-MOS transistor 12-4 are coupled to a same voltage source. That is to say, during the operation of the SA 10, the on and off times of the first N-MOS transistor 12-1 and the second N-MOS transistor 12-2 are the same, while the on and off times of the third N-MOS transistor 12-3 and the fourth N-MOS transistor 12-4 are the same.

In some implementations, the SA 10 also comprises a fifth N-MOS transistor 15, which is coupled with the first N-MOS transistor 12-1 and the third N-MOS transistor 12-3, respectively.

The fifth N-MOS transistor 15 is capable of being controlled with a gate voltage of not less than 1.5V, and is configured to control the pre-charging of the first bit line 30-1 and the second bit line 30-2.

In some implementations, a thickness of the gate oxide layer of the fifth N-MOS transistor 15 is at least twice that of the gate oxide layer of the first transistor 11. Therefore, the fifth N-MOS transistor 15 is capable of being controlled with a higher gate voltage compared to the first transistor 11.

In some implementations, the fifth N-MOS transistor is configured to control the conduction between the pre-charging voltage source and the SA 10, and the pre-charging voltage source is configured to pre-charge the bit line 30. Pre-charging refers to the process of flattening the voltages of the first bit line 30-1 and the second bit line 30-2 before data reading and writing. Only after pre-charging, can the SA 10 sense the voltage difference formed by the charging and discharging of the memory cell on the first bit line 30-1 and the second bit line 30-2.

In some implementations, the reference voltage Vref provided by the pre-charging voltage source is VDDTH/2. After flattening the voltages of the first bit line 30-1 and the second bit line 30-2 to VDDTH/2, for example, if the memory cell connected with the first bit line stores data 1, the memory cell will discharge slightly to the first bit line 30-1, causing the voltage of the first bit line 30-1 to be slightly higher than that of the second bit line 30-2, thereby forming a voltage difference; if the memory cell connected with the first bit line stores data 0, the first bit line 30-1 will charge the memory cell, causing the voltage of the first bit line 30-1 to be slightly lower than that of the second bit line 30-2, thereby forming a voltage difference.

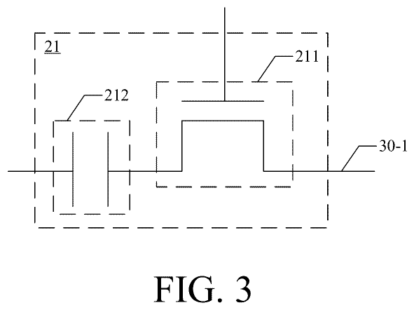

In some implementations, the plurality of memory cells 20 comprise a first memory cell 21, the bit line 30 comprises the first bit line 30-1. The structure of the first memory cell 21 is as shown in FIG. 3, and the first memory cell 21 comprises a transistor structure 211 and a capacitor structure 212. The transistor structure 211 is coupled to the first bit line 30-1 and the capacitor structure 212, respectively.

The first memory cell 21 reflects whether a binary bit is to store data 1 or data 0 employing the amount of charge stored by the capacitor structure 212. In some implementations, when a charge is stored in the capacitor structure 212, the first memory cell 21 stores data 1, and when no charge is stored in the capacitor structure 212, the first memory cell 21 stores data 0. That is to say, the capacitor structure 212 is configured to store data. The transistor structure 211 is configured to control the connection between the capacitor structure 212 and the first bit line 30-1. In an example, when data is to be read from or written to the first memory cell 21, the word line (not shown in FIG. 3) coupled with the gate of the transistor structure 211 will turn on the transistor structure 211, thus allowing the capacitor structure 212 to charge and discharge through the first bit line 30-1.

In some implementations, there is a leakage phenomenon in the transistor structure 211, resulting in the amount of the charge stored on capacitor structure 212 being insufficient to correctly distinguish data, and leading to data corruption. Therefore, it is desired to periodically charge the first memory cell 21. Due to this timed refresh feature, the first memory cell 21 can be regarded as a “dynamic” memory cell, that is, the first memory cell 21 belongs to a DRAM memory cell.

In some implementations, refer to FIG. 2, the SA 10 also comprises a sixth N-MOS transistor 16 and a seventh N-MOS transistor 17. The sixth N-MOS transistor 16 is configured to control the connection between the first data path and the first bit line 30-1, and the seventh N-MOS transistor 17 is configured to control the connection between the second data path and the second bit line 30-2. The first data path is configured to read data stored in the memory cell from the first bit line 30-1, or to write data to the memory cell through the first bit line 30-1. The second data path is configured to read data stored in the memory cell from the second bit lines 30-2, or to write data to the memory cell through the second bit lines 30-2.

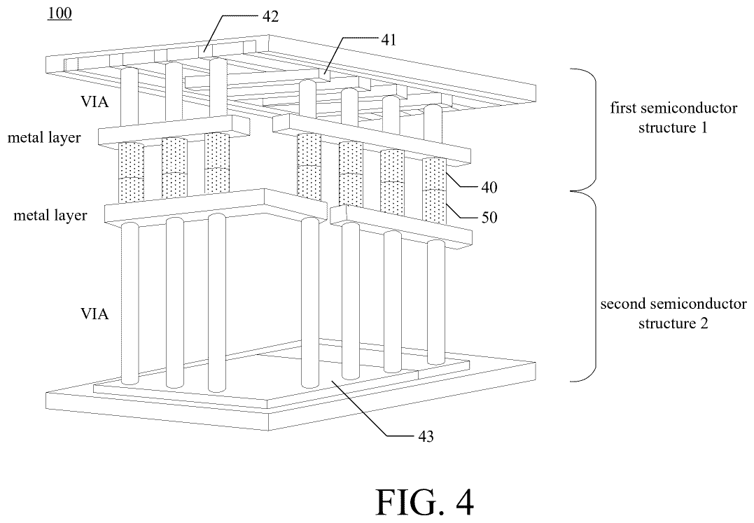

In some implementations, refer to FIG. 4, the memory 100 comprises a first semiconductor structure 1 and a second semiconductor structure 2. A plurality of memory cells 20 (not shown in FIG. 4) and a first bonding structure 40 are formed in the first semiconductor structure 1, the SA 10 (not shown in FIG. 4) and a second bonding structure 50 are formed in the second semiconductor structure, and the first semiconductor structure 1 and the second semiconductor structure 2 are bonded to each other through the first bonding structure 40 and the second bonding structure 50.

Bonding refers to a technique of combining two semiconductor structures through various forces (such as intermolecular and interatomic forces) under certain conditions after certain treatments.

A bonding structure is a structure configured to connect two different semiconductor structures. The bonding structure can comprise Cu (copper), Ni (nickel), Sn (tin), Ag (silver), or any other suitable bonding material.

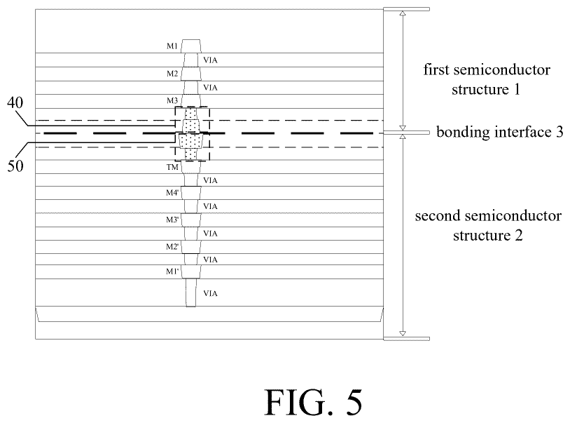

In some implementations, refer to FIG. 5, through a bonding process, the first bonding structure 40 and the second bonding structure 50 are made to melt at the bonding interface 3, thereby bonding the first semiconductor structure 1 and the second semiconductor structure 2. The bonding interface is a plane between two semiconductor structures that are bonded.

In some implementations, refer to FIG. 4, a word line structure 41 and a bit line structure 42 in the first semiconductor structure 1 are coupled to a metal layer in the first semiconductor structure 1 through a VIA (via), and a peripheral circuit 43 in the second semiconductor structure 2 is coupled to a metal layer in the second semiconductor structure 2 through the VIA, and the metal layers are configured to form a metal wire connecting the devices in the semiconductor structures. In some implementations, the first bonding structure 40 and the second bonding structure 50 are configured to couple the metal layer in the first semiconductor structure 1 and the metal layer in the second semiconductor structure 2, thereby coupling the word line structure 41 and the bit line structure 42 in the first semiconductor structure 1 to the peripheral circuit 43 in the second semiconductor structure 2. After coupling the word line structure 41 and the bit line structure 42 in the first semiconductor structure 1 to the peripheral circuit 43 in the second semiconductor structure 2, the memory cell (not shown in FIG. 4) coupled with the word line structure 41 and the bit line structure 42 in the first conductor structure 1 is coupled to the peripheral circuit 43 in the second semiconductor structure 2.

It should be noted that, as an example, both the first semiconductor structure 1 and the second semiconductor structure 2 shown in FIG. 4 only contain one layer of metal. The layout and amount of metal layers and VIA in the memory should be set according to actual needs, and the present application is not limited thereto. For example, refer to FIG. 5, the first semiconductor structure 1 comprises metal layers M1, M2, and M3, which are connected layer by layer through VIA. The second semiconductor structure 2 comprises metal layers M1′, M2′, M3′, M4′, and TM, which are connected layer by layer through VIA. The first bonding structure 40 and the second bonding structure 50 are configured to couple the metal layer M3 in the first semiconductor structure 1 to the metal layer TM in the second semiconductor structure 2.

The aforementioned metal layers and VIA can comprise Cu, Al (aluminum), Ru (ruthenium), Co (cobalt), W (tungsten) or any other suitable conductive materials, and the present application is not limited thereto.

In some implementations, the aforementioned memory cell, peripheral circuit, VIA, and metal layer are formed in the dielectric stack in the first semiconductor structure 1 and the second semiconductor structure 2, and the dielectric stack can comprise borosilicate glass (BPSG), undoped silicate glass (USG), phosphosilicate glass (PSG), tetraethyl orthosilicate (EOS), SiO2, CuO (copper oxide), spin coated dielectric (SOD), or any other suitable dielectric, and the present application is not limited thereto. Similar to metal layers, the aforementioned dielectric stack can also be divided into a plurality of dielectric layers. In an example, different structures are formed in different dielectric layers, and different dielectric layers comprise different dielectrics.

Since the SA 10 employs a second type transistor with a thicker gate oxide layer, more space is needed to accommodate the aforementioned second type transistor. In the aforementioned implementation, a plurality of memory cells 20 are formed in the first semiconductor structure 1, and the peripheral circuit (comprising the SA 10) is formed in the second semiconductor structure 2. This can provide more abundant placement space for the transistor layout of the SA 10, and effectively reduce the area cost brought by the peripheral circuit to the memory.

That how the above design can reduce the area of the memory is introduced below through the following implementations.

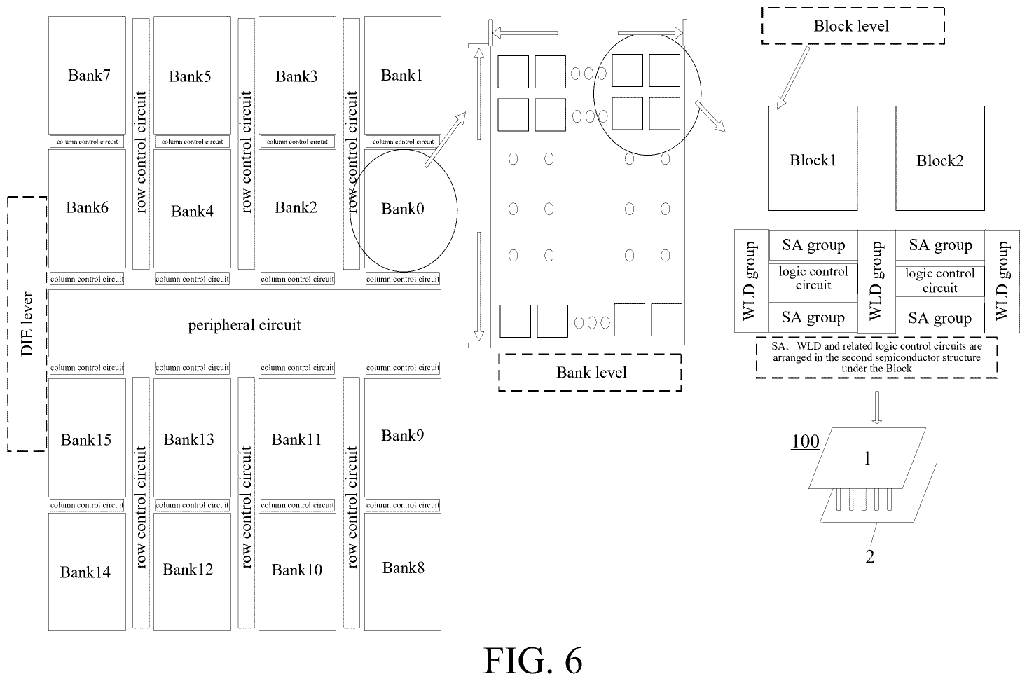

Refer to FIG. 6, in some implementations, the memory 100 comprises a multi-level architecture from large to small, wherein a Die (die) level corresponds to the memory 100. The memory 100 comprises 16 memory banks such as Bank0, Bank1, . . . , Bank15, a row control circuit (such as a row decoder) for controlling rows in a memory bank, a column control circuit (such as a column decoder) for controlling columns in the memory bank, and peripheral circuits other than the row control circuit and column control circuit aforementioned. The Bank level corresponds to the Bank (such as Bank0) comprised in memory 100. A Block (block) level corresponds to a memory cell array (such as Block1 and Block2) in the Bank. For example, a memory cell array comprises 1000×1000 memory cells. Each memory cell array has a corresponding WLD (Word Line Driver) group and SA group. The WLD group comprises a plurality of WLDs, and the SA group comprises a plurality of SAs. The WLD group is configured to provide voltage to the corresponding word lines of the memory cell array. When the memory 100 is placed in the manner as shown in FIG. 6, the second semiconductor structure 2 can be referred to as being placed below the first semiconductor structure 1. Correspondingly, the SA group, WLD group, and related logic control circuits for controlling the aforementioned SA group and WLD group, which correspond to the memory cell array (such as Block1 and Block2), can also be referred to as being placed below the memory cell array. It can be seen that in the example in FIG. 6, the SA group and the logic control circuit are completely reduced being under the corresponding memory cell array, without occupying any additional area of the memory.

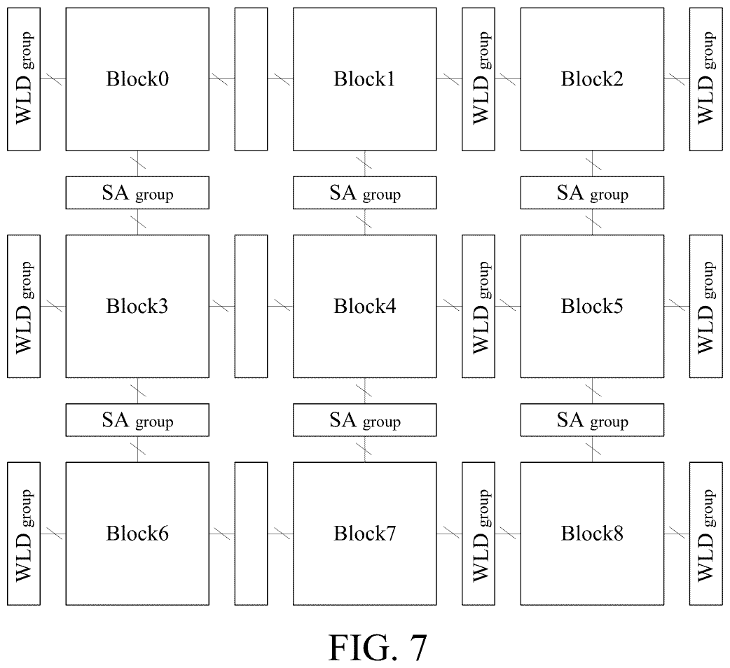

Refer to FIG. 7, in some implementations, two memory cell arrays are coupled to a same WLD group or SA group, thereby achieving the sharing of the WLD group or the SA group between the two memory cell arrays. In some implementations, different SA groups coupled to a same memory cell array are coupled with bit lines of different columns in the memory cell array. For example, after dividing the columns into odd columns and even columns based on the physical addresses of the columns in the memory cell array, the SA group coupled with Block0 and Block3 are coupled with the bit lines of the odd columns in Block0 and Block3, respectively, and the SA group coupled with Block3 and Block6 are coupled with the bit lines of the even columns in Block3 and Block6, respectively. In some implementations, different WLD groups coupled to a same memory cell array are coupled to the word lines of different rows in the memory cell array. For example, after dividing the rows into odd rows and even rows based on the physical addresses of the rows in the memory cell array, the WLD group coupled with Block0 and Block1 is coupled with the word lines of odd rows in Block0 and Block1, respectively, and the WLD group coupled with Block1 and Block2 is coupled with the word lines of even rows in Block1 and Block2, respectively. In the example in FIG. 7, an area needs to be reserved between two memory cell arrays for placing the WLD group or the SA group, resulting in an increase in the area of the memory.

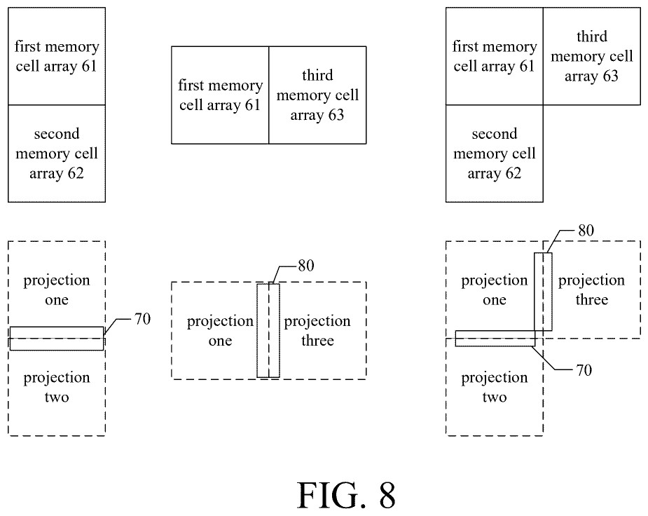

Refer to FIG. 8, in some implementations, a first memory cell array 61 is formed in the first semiconductor structure 1 (not shown in FIG. 8), the first memory cell array 61 comprises the first memory cell 21 (not shown in FIG. 8) of a plurality of memory cells 20 (not shown in FIG. 8), the first SA group 70 is formed in the second semiconductor structure 2 (not shown in FIG. 8), and the first SA group 70 comprises the SA 10 (not shown in FIG. 8).

The first SA group 70 is coupled to the first memory cell array 61, and at least a portion of a projection of the first SA group 70 on a first plane overlaps with a projection of the first memory cell array 61 on the first plane, wherein the first plane is parallel to the bonding interface 3 between the first semiconductor structure 1 and the second semiconductor structure 2 (not shown in FIG. 8).

It should be noted that, as an example, FIG. 8 illustrates the first plane as the plane where the first SA group 70 and the first WLD group 80 are located. The first plane can be any plane parallel to the bonding interface 3, and the present application is not limited thereto. Projection one in FIG. 8 is the projection of the first memory cell array 61, projection two is the projection of the second memory cell array 62, and projection three is the projection of the third memory cell array 63.

In some implementations, the projection of the first SA group 70 on the first plane entirely overlaps with the projection of the first memory cell array 61 on the first plane.

In some implementations, the projection of the first SA group 70 on the first plane partially overlaps with the projection of the first memory cell array 61 on the first plane.

In some implementations, the second memory cell array 62 is further formed in the first semiconductor structure 1, and the second memory cell array 62 comprises the second memory cell 22 of the plurality of memory cells 20 (not shown in FIG. 8).

In some implementations, the first SA group 70 is also coupled to the second memory cell array 62, and at least another portion of the projection of the first SA group 70 on the first plane overlaps with a projection of the second memory cell array 62 on the first plane. That is to say, in the case that the first SA group 70 is coupled with the first memory cell array 61 and the second memory cell array 62 respectively, the projection of the first SA group 70 on the first plane partially overlaps with the projection of the first memory cell array 61 on the first plane, and partially overlaps with the projection of the second memory cell array 62 on the first plane.

In some implementations, in the case that the first SA group 70 is coupled to the first memory cell array 61 and the second memory cell array 62 respectively, the projection of the first SA group 70 on the first plane entirely overlaps with the projection of the first memory cell array 61 on the first plane, or the projection of the first SA group 70 on the first plane entirely overlaps with the projection of the second memory cell array 62 on the first plane.

Refer to FIG. 8, in some implementations, a first memory cell array 61 is formed in the first semiconductor structure, a first WLD group 80 is formed in the second semiconductor structure 2, and the first WLD group 80 comprises a plurality of WLDs.

The first WLD group 80 is coupled to the first memory cell array 61, and at least a portion of a projection of the first WLD group 80 on the first plane overlaps with the projection of the first memory cell array 61 on the first plane.

In some implementations, the projection of the first WLD group 80 on the first plane entirely overlaps with the projection of the first memory cell array 61 on the first plane.

In some implementations, the projection of the first WLD group 80 on the first plane partially overlaps with the projection of the first memory cell array 61 on the first plane.

In some implementations, a third memory cell array 63 is also formed in the first semiconductor structure 1. The first memory cell array, the second memory cell array, and the third memory cell array aforementioned are different memory cell arrays.

In some implementations, the first WLD group 80 is also coupled to the third memory cell array 63, and at least a portion of the projection of the first WLD group 80 on the first plane overlaps with the projection of the third memory cell array on the first plane. That is to say, in the case that the first WLD group 80 is coupled to the first memory cell array 61 and the second memory cell array 62 respectively, the projection of the first WLD group 80 on the first plane partially overlaps with the projection of the first memory cell array 61 on the first plane, and partially overlaps with the projection of the third memory cell array 63 on the first plane.

In some implementations, in the case that the first WLD group 80 is coupled to the first memory cell array 61 and the second memory cell array 62 respectively, the projection of the first WLD group 80 on the first plane entirely overlaps with the projection of the first memory cell array 61 on the first plane, or the projection of the first WLD group 80 on the first plane entirely overlaps with the projection of the third memory cell array 63 on the first plane.

In summary, refer to FIG. 8, if at least one of the memory array (the first memory cell array 61, the second memory cell array 62, and the third memory cell array 63), the first SA group 70, or the first WLD group 80 is projected onto the first plane, the projection of at least one of the first SA group 70 or the first WLD group 80 will not occupy any area other than the projection of the memory cell array. Therefore, the first memory cell array 61 and the second memory cell array 62 can be placed relatively compactly, because it needs not to reserve the area for the first SA group 70. The first memory cell array 61 and the third memory cell array 63 can also be placed relatively compactly, because it needs not to reserve the area for the first WLD group 80. It can be seen that the above design reduces the area between memory cell arrays, thereby effectively reducing the area of the memory.

The technical solution provided in the implementations of the present application can reduce, by providing a second transistor controlled by a gate voltage not less than 1.5V in the sensing amplifier of the memory, the time dependent dielectric breakdown problem in the sensing amplifier caused by some transistors requiring being controlled under a higher gate voltage, thereby improving the reliability of the memory.

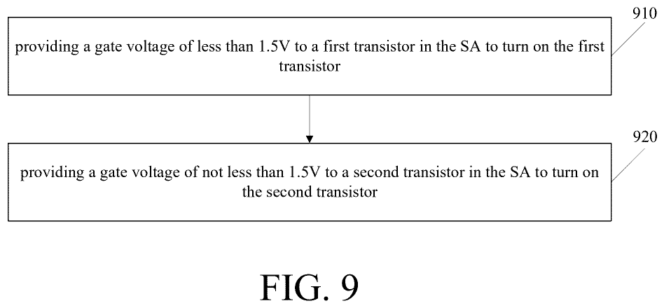

Refer to FIG. 9, it illustrates a schematic diagram of the operation method of the memory provided in one implementation of the present application. The memory comprises the SA, and various operations of the method can be executed by the peripheral circuit in the memory. The operations comprised in the method can be executed in any order, and the method comprises at least one of the following operations 910 to 920.

Operation 910: providing a gate voltage of less than 1.5V to the first transistor in the SA to turn on the first transistor.

In some implementations, a gate voltage greater than or equal to 0.8V and less than or equal to 1.3V is provided to the first transistor to turn on the first transistor.

Operation 920: providing a gate voltage of not less than 1.5V to the second transistor in the SA to turn on the second transistor.

In some implementations, a gate voltage greater than or equal to 1.5V and less than or equal to 2.2V is provided to the second transistor to turn on the second transistor.

In some implementations, the second transistor comprises a first N type metal oxide semiconductor N-MOS transistor, a second N-MOS transistor, a third N-MOS transistor, and a fourth N-MOS transistor. Operation 920 comprises at least one of the following sub-operations:
1. Providing a gate voltage of not less than 1.5V to both the first and second N-MOS transistors within a first set time to turn on the first and second N-MOS transistors simultaneously within the first set time.
2. Providing a gate voltage of not less than 1.5V to both the third and fourth N-MOS transistors within a second set time to turn on the third and fourth N-MOS transistors simultaneously within the second set time.

In some implementations, a gate voltage of not less than 1.5V is provided to the fifth N-MOS transistor in the SA within a third set time to turn on the fifth N-MOS transistor and the fifth N-MOS transistor is configured to control the pre-charging of the bit lines in the memory.

In some implementations, a gate voltage greater than or equal to 1.5V and less than or equal to 2.2V is provided to the fifth N-MOS transistor within the third set time to turn on the second transistor.

The first set time, second set time, and third set time aforementioned are all set by technical personnel as needed, and the present application does not limit them.

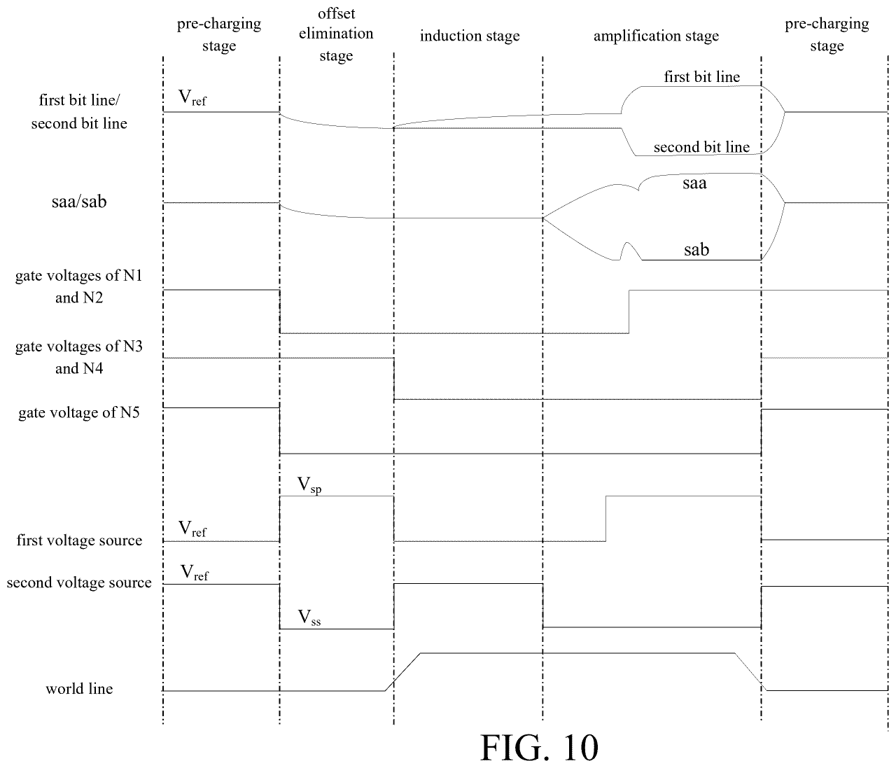

Refer to FIG. 10, it illustrates a schematic diagram of the operation timing of the sensing amplifier provided in one implementation of the present application. N1, N2, N3, N4, and N5 in FIG. 10 refer to the first N-MOS transistor, the second N-MOS transistor, the third N-MOS transistor, the fourth N-MOS transistor, and the fifth N-MOS transistor. FIG. 10 divides the operation of the SA into four stages, namely a pre-charging stage, an offset elimination stage, an induction stage, and an amplification stage.

For example, refer to FIG. 2, in the pre-charging stage, the first voltage source 13, the second voltage source 14, and the pre-charging voltage source of the memory 100 all provide a reference voltage Vref (e.g. 0.5V), and the first N-MOS transistor 12-1, the second N-MOS transistor 12-2, the third N-MOS transistor 12-3, the fourth N-MOS transistor 12-4, and the fifth N-MOS transistor 15 are all turned on through a gate voltage of not less than 1.5V (e.g. 1.8V). In this stage, refer to FIG. 10, the voltage of the first bit line 30-1 and the second bit line 30-2 are both flattened to the reference voltage Vref.

In the offset elimination stage, the first voltage source 13 of the memory 100 provides a positive voltage Vsp (such as 1V) relative to the reference voltage Vref, and the second voltage source 14 provides a negative voltage Vss (such as 0V) relative to the reference voltage Vref. The turn-on of the first N-MOS transistor 12-1, the second N-MOS transistor 12-2, and the fifth N-MOS transistor 15 is stopped, and the third N-MOS transistor 12-3 and the fourth N-MOS transistor 12-4 continues to be turned on through a gate voltage of not less than 1.5V (such as 1.8V). In this stage, refer to FIG. 10, as the voltages on the first bit line 30-1 and the second bit line 30-2 make a certain compensation for the offset noise, the voltages on the first bit line 30-1 and the second bit line 30-2 slightly decrease.

In the induction stage, the first voltage source 13 and the second voltage source 14 provide a reference voltage Vref, the turn-on of the third N-MOS transistor 12-3 and the fourth N-MOS transistor 12-4 is stopped, and the voltage of the word line coupled with the first memory cell 21 is raised, and thus switching on the first memory cell 21 and the first bit line 30-1. As the first memory cell 21 stores data 1, it applies VDDTH (such as 1V) to the first bit line 30-1, slightly pulling up the voltage of the first bit line 30-1. In this stage, refer to FIG. 10, the first bit line 30-1 and the second bit line 30-2 form a weak voltage difference.

In the amplification stage, after the second voltage source 14 provides a negative voltage Vss, the first voltage source 13 provides a positive voltage Vsp and the first N-MOS transistor 12-1 and the second N-MOS transistor 12-2 are turned on with a gate voltage of not less than 1.5V (e.g. 1.8V). In this stage, refer to FIG. 10, the weak voltage difference formed between the first bit line 30-1 and the second bit line 30-2 is amplified. At this point, data 1 can be read from the first bit line 30-1. In an example, during the amplification phase, data 0 can also be written to the first memory cell 21 through the first bit line 30-1 (the corresponding potential change is not shown in FIG. 10).

In summary, the first set time comprises a portion of the time of the pre-charging stage and the amplification stage, the second set time comprises the pre-charging stage and the offset elimination stage, and the third set time comprises the pre-charging stage.

In some implementations, the aforementioned pre-charging stage is triggered by a pre-charge command sent by the memory controller. The aforementioned offset elimination stage, induction stage, and amplification stage are triggered by an active command sent by the memory controller. The active command is configured to activate the Bank in the memory.

Turning on the aforementioned second transistor with a higher gate voltage can increase the turn-on rate of the second transistor, optimize the operation timing of the SA, and thus accelerate the storage rate of the memory. For example, the technical solution provided in the implementations of the present application can turn on the first N-MOS transistor and the second N-MOS transistor more quickly during the amplification stage, thereby shortening the write recovery time of the memory. The write recovery time is the clock cycle that is desired to be waited for after the bank in the memory is activated and the write operation is performed until pre-charging.

Turning on the aforementioned fifth N-MOS transistor with a higher gate voltage can increase the turn-on rate of the fifth N-MOS transistor, optimize the operation timing of the SA in the pre-charging stage, and thus accelerate the storage rate of the memory.

The technical solution provided in an implementation of the present application can improve, by providing a gate voltage of not less than 1.5V to the second transistor in the SA, the turn-on rate of the second transistor, thus optimize the operation timing of the SA and accelerate the storage rate of the memory.

It should be noted that the implementations of the method provided in the present application can correspond to the implementations of the memory. For details not disclosed in the implementations of the method in the present application, reference can be made to the implementations of the memory in the present application.

In some implementations, a memory system is also provided, which may comprise a controller and a memory provided in any one of the implementations of the present application, the controller being coupled to the aforementioned memory to control the storage of data in the aforementioned memory.

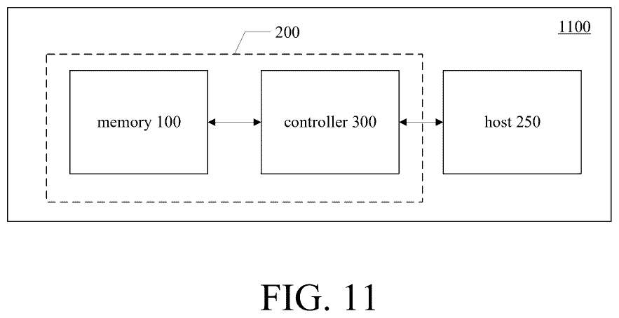

Refer to FIG. 11, as an example, it illustrates a structure block diagram of an electronic device provided in one implementation of the present application. The electronic device 1100 comprises a memory system 200 and a host 250. The memory system 200 comprises a controller 300 and a memory 100 provided in any one implementation of the present application. The electronic device 1100 can be a mobile phone, a desktop computer, a laptop, a tablet, a car computer, a game console, a printer, a positioning device, a wearable electronic device, a smart sensor, a virtual reality (VR) device, an augmented reality (AR) device, or any other suitable electronic device having a memory system therein. The host 250 can be a processor for electronic devices, such as a central processing unit (CPU), or a system on chip (SoC), such as an application processor (AP). The host 250 can be configured to send data to or receive data from memory 100. In some implementations, the controller 300 is coupled to the memory 100 and the host 250, and is configured to control the memory 100. The controller 300 can manage data stored in memory 100 and communicate with the host 250. The controller 300 can be configured to control the operations of the memory 100, such as read, write, and refresh operations. The controller 300 can also be configured to manage various functions related to data stored or to be stored in memory 100, comprising but not limited to refresh and timing control, command/request conversion, buffering and scheduling, and power management. In some implementations, the controller 300 is also configured with a maximum memory capacity, the number of memory groups, a memory type and speed, memory particle data depth and data width, and other important parameters that the electronic device can use. Any other suitable functions can also be performed by the controller 300. The controller 300 can communicate with external devices (such as the host 250) based on specific communication protocols. For example, the controller 300 can communicate with external devices through at least one of various interface protocols, such as a universal serial bus (USB) protocol, a multimedia card (MMC) protocol, a peripheral component interconnect (PCI) protocol, a PCI-express (PCIE) protocol, an advanced technology attachment (ATA) protocol, a serial ATA protocol, a parallel ATA protocol, a small computer system interface (SCSI) protocol, an enhanced small disk interface (ESDI) protocol, an integration drive electronics (IDE) protocol, a firewire protocol, etc. Furthermore, it should be noted that the memory 100 coupled with the controller 300 can be one or more, and the present application is not limited thereto.

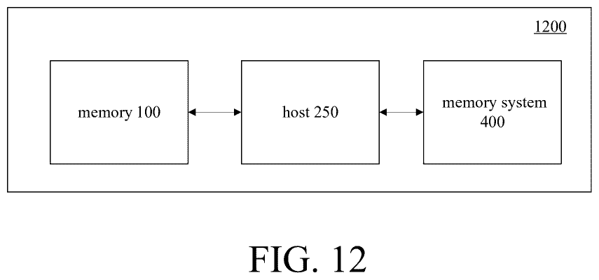

Refer to FIG. 12, as an example, it illustrates a structure block diagram of an electronic device provided in another implementation of the present application. The electronic device 1200 comprises: a memory system 400, a host 250, and a memory 100 provided in any one implementation of the present application. The host 250 can be a processor of an electronic device, such as a CPU, and the host 250 is coupled to the memory 100 and the memory system 400, respectively. In some implementations, the memory 100 may be a memory configured to temporarily store operational data of the processor (the host 250), and the memory 100 may be a volatile memory (VM), such as DRAM. The memory system 400 may comprise a non-volatile memory (NVM) that is different from the memory 100, such as a flash memory. The memory system 400 may also comprise a controller coupled with the non-volatile memory, such as a flash memory controller. In some implementations, the memory system 400 may also comprise a controller for the memory 100, such as a DRAM controller, which can be configured to control the temporary storage of data stored in the memory system 400 into the memory 100. Furthermore, it should be noted that the memory 100 coupled with the host 250 can be one or more, and the present application is not limited thereto.

In summary, the memory provided in the implementations of the present application can be coupled with the host through the controller or directly coupled with the host, and the present application is not limited thereto.

Implementations of the present application provide a memory, an operation method, a memory system, and an electronic device. The technical solutions provided in the implementations of the present application are as follows:

According to one aspect of the implementations of the present application, a memory is provided, wherein the memory comprises a sensing amplifier SA and a plurality of memory cells, wherein the plurality of memory cells are coupled to a bit line, the bit line is connected to the SA, and the SA comprises a first transistor and a second transistor;

wherein the first transistor is coupled with a first voltage source of the SA or a second voltage source of the SA; and

wherein the second transistor is coupled with the bit line and capable of being controlled with a gate voltage of not less than 1.5V.

According to one aspect of the implementations of the present application, an operation method of a memory is provided, wherein the memory comprises a sensing amplifier SA, and the method comprises:
providing a gate voltage of less than 1.5V to a first transistor in the SA to turn on the first transistor; and
providing a gate voltage of not less than 1.5V to a second transistor in the SA to turn on the second transistor.

According to one aspect of the implementations of the present application, a memory system is provided, wherein the memory system comprises a controller and a memory, wherein the controller is coupled to the memory to control the memory to store data, wherein the memory comprises a sensing amplifier SA and a plurality of memory cells, wherein the plurality of memory cells are coupled to a bit line, the bit line is connected to the SA, and the SA comprises a first transistor and a second transistor;
wherein the first transistor is coupled with a first voltage source of the SA or a second voltage source of the SA; and
wherein the second transistor is coupled with the bit line and capable of being controlled with a gate voltage of not less than 1.5V.

According to one aspect of the implementations of the present application, an electronic device is provided, wherein the electronic device comprises a host and a memory system coupled to the host, wherein the memory system comprises a controller and a memory, wherein the controller is coupled to the memory to control the memory to store data, wherein the memory comprises a sensing amplifier SA and a plurality of memory cells, wherein the plurality of memory cells are coupled to a bit line, the bit line is connected to the SA, and the SA comprises a first transistor and a second transistor;
wherein the first transistor is coupled with a first voltage source of the SA or a second voltage source of the SA; and
wherein the second transistor is coupled with the bit line and capable of being controlled with a gate voltage of not less than 1.5V.

The technical solution provided in the implementations of the present application can bring the following technical effects:

By providing a second transistor controlled by a gate voltage not less than 1.5V in the sensing amplifier of the memory, the time dependent dielectric breakdown problem in the sensing amplifier caused by some transistors requiring being controlled under a higher gate voltage can be reduced, thereby improving the reliability of the memory.

The term “a plurality of” mentioned herein refers to two or more. “At least one of” describes the association relationship of associated objects, indicating that there can exist three types of relationships, for example, “at least one of A or B” can indicate: the existence of A alone, the coexistence of A and B, and the existence of B alone. The character “/”, in an example, indicates that the associated objects are in an “or” relationship.

The above are example implementations of the present application and are not intended to limit the present application. Any modifications, equivalent substitutions, improvements, etc. made within the spirit and principles of the present application shall be comprised within the scope of protection of the present application.

What is claimed is:

1. A memory comprising a sensing amplifier (SA) and a plurality of memory cells, wherein the plurality of memory cells are coupled to a bit line, the bit line is connected to the SA, and the SA includes a first transistor and a second transistor;
wherein the first transistor is coupled with a first voltage source of the SA or a second voltage source of the SA; and
wherein the second transistor is coupled with the bit line and capable of being controlled with a gate voltage of not less than 1.5V.

2. The memory of claim 1, wherein the second transistor includes a first N type metal oxide semiconductor (N-MOS transistor), a second N-MOS transistor, a third N-MOS transistor, and a fourth N-MOS transistor;
wherein the bit line includes a first bit line and a second bit line, the first N-MOS transistor and the fourth N-MOS transistor are respectively coupled to the first bit line, and the second N-MOS transistor and the third N-MOS transistor are respectively coupled to the second bit line; and
the first N-MOS transistor and the second N-MOS transistor are controlled with a same gate voltage, and the third N-MOS transistor and the fourth N-MOS transistor are controlled with a same gate voltage.

3. The memory of claim 2, wherein the SA further includes a fifth N-MOS transistor, the fifth N-MOS transistor is coupled with the first N-MOS transistor and the third N-MOS transistor respectively; and
the fifth N-MOS transistor is capable of being controlled with a gate voltage of not less than 1.5V, and is configured to control pre-charging of the first bit line and the second bit line.

4. The memory of claim 1, wherein the memory includes a first semiconductor structure and a second semiconductor structure, the plurality of memory cells and a first bonding structure are formed in the first semiconductor structure, and the SA and a second bonding structure are formed in the second semiconductor structure, the first semiconductor structure and the second semiconductor structure are bonded to each other through the first bonding structure and the second bonding structure.

5. The memory of claim 4, wherein a first memory cell array is formed in the first semiconductor structure, the first memory cell array includes a first memory cell of the plurality of memory cells, a first SA group is formed in the second semiconductor structure, and the first SA group includes the SA; and
the first SA group is coupled to the first memory cell array, at least a portion of a projection of the first SA group on a first plane overlaps with a projection of the first memory cell array on the first plane, and the first plane is parallel to a bonding interface between the first semiconductor structure and the second semiconductor structure.

6. The memory of claim 5, wherein a second memory cell array is further formed in the first semiconductor structure, and the second memory cell array includes a second memory cell of the plurality of memory cells; and
the first SA group is further coupled to the second memory cell array, and at least another portion of the projection of the first SA group on the first plane overlaps with a projection of the second memory cell array on the first plane.

7. The memory of claim 4, wherein a first memory cell array is formed in the first semiconductor structure, a first word line driver (WLD) group is formed in the second semiconductor structure, and the first WLD group includes a plurality of WLDs; and
the first WLD group is coupled to the first memory cell array, at least a portion of a projection of the first WLD group on a first plane overlaps with a projection of the first memory cell array on the first plane, and the first plane is parallel to a bonding interface between the first semiconductor structure and the second semiconductor structure.

8. The memory of claim 7, wherein a third memory cell array is further formed in the first semiconductor structure; and
the first WLD group is further coupled to the third memory cell array, and at least a portion of the projection of the first WLD group on the first plane overlaps with a projection of the third memory cell array on the first plane.

9. The memory of claim 1, wherein a thickness of a gate oxide layer of the second transistor is at least twice that of a gate oxide layer of the first transistor.

10. The memory of claim 1, wherein the plurality of memory cells include a first memory cell, the bit line includes a first bit line, the first memory cell includes a transistor structure and a capacitor structure, and the transistor structure is coupled to the first bit line and the capacitor structure, respectively.

11. An operation method of a memory, wherein the memory includes a sensing amplifier (SA), and the method comprises:
providing a gate voltage of less than 1.5V to a first transistor in the SA to turn on the first transistor; and
providing a gate voltage of not less than 1.5V to a second transistor in the SA to turn on the second transistor.

12. The operation method of claim 11, wherein the second transistor includes a first N type metal oxide semiconductor (N-MOS transistor), a second N-MOS transistor, a third N-MOS transistor, and a fourth N-MOS transistor, and the providing a gate voltage of not less than 1.5V to a second transistor in the SA to turn on the second transistor includes:
providing a gate voltage of not less than 1.5V to the first N-MOS transistor and the second N-MOS transistor within a first set time to simultaneously turn on the first N-MOS transistor and the second N-MOS transistor within the first set time; and
providing a gate voltage of not less than 1.5V to the third N-MOS transistor and the fourth N-MOS transistor within a second set time to simultaneously turn on the third N-MOS transistor and the fourth N-MOS transistor within the second set time.

13. The operation method of claim 11, wherein the operation method further includes providing a gate voltage of not less than 1.5V to a fifth N-MOS transistor in the SA within a third set time to turn on the fifth N-MOS transistor, wherein the fifth N-MOS transistor is configured to control pre-charging of a bit line in the memory.

14. A memory system comprising a controller and a memory, wherein the controller is coupled to the memory to control the memory to store data, wherein the memory includes a sensing amplifier (SA) and a plurality of memory cells, the plurality of memory cells are coupled to a bit line, the bit line is connected to the SA, and the SA includes a first transistor and a second transistor;
wherein the first transistor is coupled with a first voltage source of the SA or a second voltage source of the SA; and
wherein the second transistor is coupled with the bit line and capable of being controlled with a gate voltage of not less than 1.5V.

15. The memory system of claim 14, wherein the second transistor includes a first N type metal oxide semiconductor (N-MOS transistor), a second N-MOS transistor, a third N-MOS transistor, and a fourth N-MOS transistor;
wherein the bit line includes a first bit line and a second bit line, the first N-MOS transistor and the fourth N-MOS transistor are respectively coupled to the first bit line, and the second N-MOS transistor and the third N-MOS transistor are respectively coupled to the second bit line; and
the first N-MOS transistor and the second N-MOS transistor are controlled with a same gate voltage, and the third N-MOS transistor and the fourth N-MOS transistor are controlled with a same gate voltage.

16. The memory system of claim 15, wherein the SA further includes a fifth N-MOS transistor, the fifth N-MOS transistor is coupled with the first N-MOS transistor and the third N-MOS transistor respectively; and
the fifth N-MOS transistor is capable of being controlled with a gate voltage of not less than 1.5V, and is configured to control pre-charging of the first bit line and the second bit line.

17. The memory system of claim 14, wherein the memory includes a first semiconductor structure and a second semiconductor structure, the plurality of memory cells and a first bonding structure are formed in the first semiconductor structure, and the SA and a second bonding structure are formed in the second semiconductor structure, the first semiconductor structure and the second semiconductor structure are bonded to each other through the first bonding structure and the second bonding structure.

18. The memory system of claim 17, wherein a first memory cell array is formed in the first semiconductor structure, the first memory cell array includes a first memory cell of the plurality of memory cells, a first SA group is formed in the second semiconductor structure, and the first SA group includes the SA; and
the first SA group is coupled to the first memory cell array, at least a portion of a projection of the first SA group on a first plane overlaps with a projection of the first memory cell array on the first plane, and the first plane is parallel to a bonding interface between the first semiconductor structure and the second semiconductor structure.

19. The memory system of claim 18, wherein a second memory cell array is further formed in the first semiconductor structure, and the second memory cell array includes a second memory cell of the plurality of memory cells; and
the first SA group is further coupled to the second memory cell array, and at least another portion of the projection of the first SA group on the first plane overlaps with a projection of the second memory cell array on the first plane.

20. The memory system of claim 17, wherein a first memory cell array is formed in the first semiconductor structure, a first word line driver (WLD) group is formed in the second semiconductor structure, and the first WLD group includes a plurality of WLDs; and
the first WLD group is coupled to the first memory cell array, at least a portion of a projection of the first WLD group on a first plane overlaps with a projection of the first memory cell array on the first plane, and the first plane is parallel to a bonding interface between the first semiconductor structure and the second semiconductor structure.
